(19) United States
(12) Patent Application Publication
(10) Pub. No.: US 2024/0378330 A1
(43) Pub. Date: Nov. 14, 2024

(54) Method and System for Optimal Engineering Design

(71) Applicants: Scott R. Hansen, Irvine, CA (US); Louisa Marie Hansen, Elsah, IL (US); Robert Edwin Hansen, Bigfork, MT (US)

(72) Inventors: Scott R. Hansen, Irvine, CA (US); Louisa Marie Hansen, Elsah, IL (US); Robert Edwin Hansen, Bigfork, MT (US)

(21) Appl. No.: 18/215,834

(22) Filed: Jun. 29, 2023

Related U.S. Application Data
(60) Provisional application No. 63/523,562, filed on Jun. 27, 2023.
(60) Provisional application No. 63/465,314, filed on May 10, 2023.

(51) Int. Cl. G06F 30/13

(52) U.S. Cl. CPC G06F 30/13; G06F 30/20; G06F 30/27; G06F 30/23

(57) ABSTRACT

The invention presents a method for optimizing the design of structures or engineering designs utilizing an Artificial Intelligence (AI) system, specifically Generative Design AI. The AI system proposes an initial design, which is then iteratively optimized by a structural or design optimization system to maximize or minimize a property under certain constraints. The optimal design is used to construct a real-world structure or object, from which real-world data is gathered under actual use conditions. This data is used to retrain the AI system, facilitating ongoing improvement of the design process. The invention can be applied to a variety of fields, including but not limited to, biomedical devices, civil structures, mechanical systems, and electronic devices, among others.

### RELATED APPLICATION

This patent application claims priority to U.S. Provisional Patent Application No. 63/465,314, filed May 10, 2023 and entitled “Numerical Engineering Design Optimization Augmented With Generative Artificial Intelligence (AI)” and also claims priority to U.S. Provisional Patent Application No. 63/523,562, filed Jun. 27, 2023 and entitled “Method and System for Optimal Engineering Design,” both of which are incorporated by reference herein in their entirety.

### BACKGROUND

The field of engineering design, which includes the design of structures, systems, devices, and components, is continuously seeking methods for improvement. The process of designing such items is complex and multifaceted, involving the consideration of numerous factors including functionality, efficiency, cost-effectiveness, safety, and regulatory compliance among others. Traditional design approaches often involve iterative refinement based on trial and error, which can be time-consuming and resource-intensive.

With the advent of advanced computational techniques and the increasing availability of data, there has been a growing interest in leveraging these resources to improve the engineering design process. Numerical optimization techniques, which use mathematical algorithms to find optimal solutions, have been increasingly applied to design problems. However, these techniques can be computationally intensive and may not always yield practical solutions.

Artificial Intelligence (AI), particularly machine learning, has also been gaining prominence in the field of engineering design. AI systems have the potential to learn from data and make predictions or decisions without being explicitly programmed to perform the task. This makes them well-suited for applications in engineering design, where they can learn from historical design data and potentially propose innovative and efficient designs.

Despite the promise of AI and numerical optimization techniques, there are still challenges in integrating these approaches into the engineering design process. One of the main challenges is the gap between the optimized designs proposed by these systems and the practical constraints and requirements of real-world applications. Additionally, the process of training and updating AI systems to improve their performance over time is not straightforward, particularly when dealing with real-world data from constructed designs.

There is, therefore, a need for systems and methods that effectively integrate AI and numerical optimization techniques into the engineering design process, and which can use real-world data to continuously improve the performance of these systems. The present invention seeks to address these needs.

Furthermore, In various engineering fields, the design and construction of structures require optimization of shapes and dimensions to meet specific performance requirements, constraints, and objectives. Conventional optimization methods often rely on manual trial-and-error or deterministic approaches in order to formulate an initial pre-optimization structure that the optimization platform will then optimize, which can be time-consuming and might not always yield optimal results.

That is, the better the starting design, oftentimes the final design will be better and closer to the true optimal design. This is true of engineering design optimization generally.

The use of artificial intelligence (AI) in structural design has recently gained significant attention, as it can potentially automate and enhance the optimization process. However, there is still a need for a comprehensive method that combines generative AI with numerical structural design optimization techniques to generate shape-optimized structures efficiently.

The work in this patent application builds on the work of a present inventor, Scott Hansen, as illustrated in the seminal structural optimization paper he co-authored with his engineering graduate thesis advisor Professor Dr. Garret Vanderplaats: Hansen, S. R. & Vanderplaats, G. N. (1990). Approximation method for configuration optimization of trusses. AIAA Journal, 28(6), 1037-1044. doi: 10.2514/3.10364, which is incorporated by reference herein. NASA Ames Research Center of Silicon Valley, California supported our prior work.

### Types of Structural Optimization

Numerical structural optimization refers to the process of finding the best design for a structure based on mathematical models and computer simulations. Here are some types of numerical structural optimization:

Topology optimization—This approach optimizes the layout of material in a structure. For example, in some structures it may determine which regions should be solid and which should be void, to meet specified performance objectives. As another non-limiting example, and with one particular class of structures, topology optimization finds optimum member sizes and joint positions (e.g., as in the Hansen and Vanderplaats AIAA publication identified above), but also determines the number of joints and how members connect the joints.

Shape optimization—This method optimizes the shape of a structure, altering its geometry to achieve specific performance goals.

Size optimization—This approach optimizes the size of components within a structure, adjusting the dimensions of various elements to meet performance criteria.

Material optimization—This method optimizes the choice of material for a structure, selecting the best material properties for each component based on the required performance characteristics.

Multi-objective optimization—This approach simultaneously optimizes several performance criteria, such as weight, stiffness, and cost, to find a design that achieves the best overall balance of these factors.

Sensitivity analysis—This method evaluates the sensitivity of a structure's performance to various design parameters, helping to identify critical features that must be optimized to achieve the desired performance.

Stochastic Optimization—This involves optimizing designs in the presence of uncertainties.

Composite Optimization—optimizes, for example, orientation, thickness, and sequence of layers in a composite laminate for a desired objective function.

Robust optimization—This approach optimizes a design to be robust to variations in material properties, loading conditions, or other uncertainties, ensuring that the structure performs well under a range of possible conditions.

These are some of the main types of numerical structural optimization that are used in engineering and design to create optimal structures that meet specific performance criteria. The invention as described herein and in the Detailed Description can be used in conjunction with one or more of these types of structural optimization, for example.

The following are provided for historical perspective in structural optimization. All of the following are incorporated by reference herein.
Schmit, L. A. (1960). Structural Design by Systematic Synthesis. Proceedings of the Second Conference on Electronic Computation, ASCE, New York, 105-122.
Vanderplaats, G. N. (1973). Method for Multidisciplinary Design Optimization. Journal of Aircraft, 10(4), 216-220.
Schmit, L. A., & Miura, H. (1966). Approximation Concepts for Structural Synthesis. Journal of the AIAA, 4(10), 1664-1670.
Vanderplaats, G. N., & Moses, F. (1972). Structural Optimization by Methods of Feasible Directions. Computers & Structures, 2(1), 165-189.
Vanderplaats, G. N. (1984). Numerical Optimization Techniques for Engineering Design: With Applications. McGraw-Hill.
Vanderplaats G N and Salajegheh E. A New Approximation Method for Stress Constraints in Structural Synthesis, AIAA Journal, Vol. 27, No. 3, pp. 352-358, March 1989.
Rozvany, G. I. N., Zhou, M., & Birker, T. (1992). Generalized Shape Optimization Without Homogenization. Structural Optimization, 4(3-4), 250-252.
Bendsøe, M. P., & Sigmund, O. (2003). Topology Optimization: Theory, Methods, and Applications. Springer Science & Business Media.
Kirsch, U. (1989). Optimum Structural Design: A Unified Approach. McGraw-Hill.
Haftka, R. T., & Gürdal, Z. (1992). Elements of Structural Optimization. Kluwer Academic Publishers.
Schmit, L. A., & Farshi, B. (1974). Some Approximation Concepts for Structural Synthesis. AIAA Journal, 12(5), 692-699.
Arora, J. S. (2012). Introduction to Optimum Design. Academic Press.
Papalambros, P. Y., & Wilde, D. J. (2000). Principles of Optimal Design: Modeling and Computation. Cambridge University Press.
Sigmund, O., & Bendsøe, M. P. (2003). Topology Optimization: Theory, Methods, and Applications. Springer Science & Business Media.
Thierauf, G. (1995). Optimum Structural Design. Springer Science & Business Media.
Eschenauer, H. A., & Olhoff, N. (1994). Topology Optimization of Structures: An Introduction. Springer Science & Business Media.
Rozvany, G. I. N. (2009). A Critical Review of Established Methods of Structural Topology Optimization. Springer Science & Business Media.
Kirsch, U. (1989). Structural Optimization: Fundamentals and Applications. Springer-Verlag.
Topping, B. H. V., & Zienkiewicz, O. C. (1997). Shape Optimization and Sequential Linear Programming. John Wiley & Sons.
G. N. Vanderplaats (1993), Thirty years of modern structural optimization, Advances in Engineering Software, Volume 16, Issue 2.
Afzal, M. et al (2020), Reinforced concrete structural design optimization: A critical review, Journal of Cleaner Production, Volume 260, 1 Jul. 2020, 120623
Ide, T., Kitajima, H., Otomori, Leiva J P & Watson B (2016). Structural optimization methods of nonlinear static analysis with contact and its application to design lightweight gear box of automatic transmission of vehicles. Struct Multidisc Optim 53, 1383-1394 (2016)
Leiva J P (2004) Topometry optimization: a new capability to perform element by element sizing optimization of structures. In: Proceedings of 10th AIAA/ISSMO symposium on multidisciplinary analysis and optimization Albany, New York, USA, 30 August-1 September, 2004-4595
Leiva J P (2011) Structural optimization methods and techniques to design efficient car bodies. In: Proceedings of international automotive body congress 2011, Troy, Michigan, USA, 9-10 November
Juan Pablo Leiva, Hong Dong, Brian Watson (2019) Structural Optimization Methods and Techniques for Additive Manufacturing, The World Congress of Structural and Multidisciplinary Optimization, May 20-24, 2019, Beijing, China
Leiva J P, Watson, B C, and Kosaka I. Modern Structural Optimization Concepts Applied to Topology Optimization, Proceedings of the 40th AIAA/ASME/ASCE/AHS/ASC Structures, Structural Dynamics, and Material Conference. St. Louis, MO, pp. 1589-1596 Apr. 12-15, 1999 GENESIS User's Manual, Version 17.0 VR&D, Inc., Colorado Springs, CO, May 2018. DOT User's Manual, Version 7.2, VR&D, Colorado Springs, CO, 2017

Again, the foregoing are all incorporated by reference herein. All publications referred to in this patent application are incorporated by reference.

### Finite Element Analysis (FEA)

An element of our earlier work includes Finite Element Analysis (FEA). An overview is as follows:

Finite Element Analysis (FEA) is a computerized method for predicting how a product reacts to real-world forces, vibration, heat, fluid flow, and other physical effects. It is widely used in the fields of mechanical engineering, civil engineering, and material science, among others. Finite element analysis allows engineers to predict the behavior of a structure under various conditions and loads, helping to identify potential problems and optimize the design without the need for physical prototypes or testing. It's a powerful tool that plays a crucial role in the design and optimization of structures in many different fields.

Typically, FEA includes steps such as:

Discretization: The first step in finite element analysis is breaking down the entire structure or system into small, simple parts called elements. This process is called discretization or meshing. These elements are usually geometrically simple shapes like triangles (in 2D) or tetrahedrons (in 3D), and the entire collection of elements (the mesh) represents the whole structure.

Element Analysis: Each element is then analyzed individually. This involves creating equations that describe the behavior of each element, considering the physical laws and forces at play. Each element's behavior is described in relation to its neighboring elements. This is possible because the geometry and properties of each element are known and simple.

System Assembly: After each element's behavior has been described, these individual element behaviors (equations) are assembled into a large system of equations that describes the behavior of the entire structure.

Solving the System: This system of equations is then solved using numerical methods, typically on a computer. The solution provides the values of the field variables, such as displacement, temperature, pressure, etc., at each point in the structure.

Post-Processing: The results are then interpreted and visualized in post-processing. This can involve creating images or animations that show how different quantities (like stress or temperature) vary throughout the structure.

Although FEA is most commonly used in structural optimization, other structural analysis approaches may be used.

### Steps in Iterative Structural Optimization

Iterative structural optimization is a process in which a structure's design is gradually improved through repeated cycles of analysis and modification. The goal of the process is to arrive at an optimal design that meets specified performance criteria and constraints. Here's a general description of how it might work:

Initial Design: The process starts with an initial design. This could be a simple, arbitrary design or a more complex design based on engineering intuition, previous designs, or suggestions from a generative artificial intelligence system.

Analysis: The initial design is then analyzed to assess its performance. This might involve calculating structural attributes such as stress, strain, displacement, or natural frequency. Finite element analysis (FEA) is a common tool used for this purpose.

Evaluation: The results of the analysis are evaluated against the performance criteria and constraints. This could involve checking whether the stress in any part of the structure exceeds a certain limit, whether the structure can support a specified load, or whether the natural frequency of the structure avoids a certain range.

Modification: Based on the results of the evaluation, the design is then modified. This might involve changing the shape, size, or material of certain parts of the structure to better meet the performance criteria and constraints. The modifications are typically guided by mathematical optimization techniques, which search for the design changes that will most improve the performance.

Iteration: The evaluation, analysis, and modification steps are repeated, with each cycle using the modified design from the previous cycle as the starting point. With each iteration, the design should improve and get closer to meeting the performance criteria and constraints.

Convergence: The iterative process continues until a satisfactory design is reached or until further iterations do not significantly improve the design. This is known as convergence.

Iterative structural optimization allows for a systematic and efficient approach to improving structural designs. It's particularly useful when dealing with complex structures and performance criteria, where intuitive or manual design approaches might struggle to find the best design.

### Iterative Topology Optimization

As noted previously, topology optimization is a mathematical approach used in structural design to find the best distribution of material within a given design space, considering specific load conditions and constraints, with the goal of maximizing the performance of the structure. It is a type of iterative structural optimization that evolves the design by adding or removing material, effectively changing the structure's topology (i.e., its ‘layout’).

Some steps in topology optimization include:

1. Define the Design Space: The process begins by defining a design space, which is the volume within which the structure can be created. This space is typically filled with a uniform distribution of material, essentially starting with a “solid” block.

2. Apply Loads and Boundary Conditions: Loads (forces, pressures, etc.) and boundary conditions (fixed points, allowed movements, etc.) are then applied to the design space. These represent the conditions the final structure will be subjected to.

3. Perform Initial Analysis: The initial design is analyzed to calculate how well it performs under the specified loads and conditions. This often involves calculating structural attributes such as stress, strain, or displacement. Finite element analysis is a common tool used for this purpose.

4. Evaluate and Modify Design: The design is evaluated against the performance objectives (such as minimizing weight or maximizing stiffness), and the design is modified based on these results. The modification typically involves removing material from areas of low stress (where it contributes little to the structural performance) and possibly adding material to areas of high stress. This process is typically guided by mathematical algorithms.

5. Iterate: Steps 3 and 4 are repeated, with each iteration using the modified design from the previous iteration. Over time, the material within the design space is redistributed to form the optimal structure.

6. Convergence: The iterative process continues until a satisfactory design is achieved or no significant improvements can be made. The result is a structure that optimally uses its material to meet the performance objectives under the specified loads and conditions.

Topology optimization allows engineers to create efficient, high-performance structures that make the best use of their material. It's particularly useful in the early design stages and can lead to innovative designs that would be difficult or impossible to achieve through traditional design methods. Note that, as previously discussed, topology optimization has other applications, such as determining the number of joints and how members connect the joints in, for example, a truss structure.

### GENESIS Structural Optimization Platform

The GENESIS structural optimization platform is a software tool developed by Vanderplaats Research & Development, Inc. that is used to design and optimize complex engineering structures. Here's how it works:

Define the problem: The user specifies the design problem they want to solve, including the geometry, material properties, loading conditions, and performance objectives for the structure.

Generate the initial design: The software creates an initial design based on the user's input, typically using finite element analysis (FEA) to model the structure's behavior under different loading conditions.

Define design variables: The user selects the design variables that can be adjusted to optimize the structure, such as the thickness of different components or the location of key features.

Set up optimization algorithm: The user selects an optimization algorithm to use, such as gradient-based optimization or genetic algorithms, and sets up the algorithm with the appropriate parameters.

Run the optimization: The software runs the optimization algorithm, adjusting the design variables to find the best possible design that meets the specified performance objectives.

Evaluate the results: The software presents the results of the optimization, including the optimized design, the changes made to the initial design, and the performance characteristics of the final structure.

Refine and iterate: Based on the results of the optimization, the user can refine the design further, adjusting the performance objectives or design variables as needed, and run the optimization again to achieve an even better design.

Overall, the GENESIS structural optimization platform uses a combination of advanced modeling techniques, optimization algorithms, and user input to create optimal designs that meet specific performance criteria, helping engineers and designers create efficient and effective structures for a wide range of applications.

### General Numerical Design Optimization

Structural optimization may be considered a specific application of numerical design optimization, which has uses far beyond just structural optimization. Numerical design optimization is a quantitative approach that utilizes mathematical models and techniques to find the optimal design parameters that maximize or minimize a specific objective function, while satisfying certain constraints. The topic is introduced by Dr. Garret Vanderplaats in his classic textbook, Vanderplaats, G. N. (1984). Numerical Optimization Techniques for Engineering Design: With Applications. McGraw-Hill, which is incorporated by reference herein.

In a general way, some steps in the numerical design optimization process may include:

Problem Definition: Clearly define the optimization problem. This includes identifying the objective function that needs to be maximized or minimized, and defining the design variables that can be adjusted in the system. Also, any constraints on the variables or the system need to be identified.

Formulation of the Objective Function: The objective function quantifies the performance of the system. It could be something like minimizing the cost or maximizing the efficiency. Formulate this function in terms of the design variables.

Formulation of Constraints: Define the constraints that restrict the design variables. These could be physical constraints (e.g., dimensions of a part cannot exceed a certain limit), economic constraints (e.g., cost of materials), or operational constraints (e.g., product must withstand a certain amount of stress).

Selection of Optimization Algorithm: Depending on the nature of the problem (e.g., linear, non-linear, integer), choose an appropriate optimization algorithm. Some common ones are Gradient Descent, Genetic Algorithms, Simulated Annealing, Particle Swarm Optimization, etc.

Implementation of the Algorithm: Implement the selected algorithm in a suitable programming language or software. During this stage, it's often necessary to create a mathematical model of your system. This model takes the design variables as input and outputs the value of the objective function and the constraints.

Solution of the Optimization Problem: Run the optimization algorithm. This step will iteratively adjust the design variables in order to find the optimal solution that minimizes or maximizes the objective function while satisfying the constraints.

Although the initial focus of the present invention relates to structural optimization, embodiments of the invention may include employing generative AI as part of a general numerical design optimization approach.

### Further Reading on Numerical Design Optimization

The following provide background on numerical design optimization. All of the following are incorporated by reference herein:
Vanderplaats, G. N. (1984). Numerical Optimization Techniques for Engineering Design: With Applications. McGraw-Hill.
Vanderplaats, G. N. (2005). Multidiscipline Design Optimization: Supported by Finite Element Analysis. Vanderplaats Research & Development, Inc.
Arora, J. S. (2012). Introduction to Optimum Design. Academic Press.
Rao, S. S. (2009). Engineering Optimization: Theory and Practice. John Wiley & Sons.
Nocedal, J., & Wright, S. (2006). Numerical Optimization. Springer Science & Business Media.
Vanderplaats, G. N. (1999). Genetic algorithms in structural optimization. In Genetic Algorithms in Engineering and Computer Science. John Wiley & Sons.
Gill, P. E., Murray, W., & Wright, M. H. (1981). Practical Optimization. Academic Press.
Papalambros, P. Y., & Wilde, D. J. (2000). Principles of Optimal Design: Modeling and Computation. Cambridge University Press.
Vanderplaats, G. N., & Venkayya, V. B. (1972). An Approximation Method for Configuration Optimization. AIAA Journal, 10(12), 1671-1675.
Boyd, S., & Vandenberghe, L. (2004). Convex Optimization. Cambridge University Press

### Generative AI

Generative AI refers to a type of artificial intelligence that creates new content, such as images, music, voice, text, or other types of data outputs, based on the patterns it learned from input data. It's a subset of machine learning where the AI models are used to generate data distributions.

Here are some of the most commonly used methods and applications of generative AI:

Generative Adversarial Networks (GANs): GANs consist of two parts, a generator and a discriminator. The generator creates samples and the discriminator evaluates them. The goal of the generator is to create samples that the discriminator can't distinguish from the real data. GANs are often used to generate realistic images, but can also be used for generating other types of data.

Variational Autoencoders (VAEs): VAEs are a type of autoencoder with a twist: instead of directly encoding input data to a fixed vector, they encode it to a distribution. When generating new samples, they sample from this distribution. VAEs are often used in applications that need a continuous, structured latent space, such as generating different styles of handwriting or interpolating between different images.

Transformer Models: Transformer models, like GPT-3, are a type of AI model that use attention mechanisms to generate text. They're trained to predict the next word in a sentence and can generate coherent and contextually relevant sentences by stringing together these predictions. This technology is used to write articles, generate conversational agents, translate languages, and even write code.

Recurrent Neural Networks (RNNs): RNNs are used for sequential data and are particularly well-suited for tasks that involve sequences, like time-series data, handwriting, and speech. They can generate new sequences that resemble the patterns in the input data.

Evolutionary Generative Adversarial Networks (E-GANs): E-GANs are a variant of GANs that use evolutionary strategies to train the discriminator, which can lead to improved stability and quality of the generated samples.

### BRIEF SUMMARY OF THE INVENTION

The present invention provides a method for optimizing the design of a structure or an engineering design using an Artificial Intelligence (AI) system, specifically, a Generative Design AI. The method includes using the AI system to propose an initial design for the structure or engineering design, followed by employing a structural or design optimization system to optimize from the initial design. The optimization system iteratively refines the design to maximize or minimize a property subject to at least one constraint, using techniques such as Finite Element Analysis or other computational modeling approaches.

The optimal design is then used to construct a real-world structure or object. Real-world data is collected from the structure or object under actual use conditions, and this data is subsequently used to retrain the AI system, allowing for continuous learning and improvement of the design process.

The structure or engineering design can include, but is not limited to, biomedical devices (such as cardiac devices), civil structures, antennas for tracking animals, hand tools used in construction, trailers for vehicle transport, components of mechanical systems, electronic devices, or components of civil infrastructure structures.

The method may also include steps such as 3D printing the real-world structure, or implanting biomedical devices into a human or animal body. The real-world structure or object may be a scale model, a component of an Internet of Things (IoT) device, or include one or more RFID tags. Real-world data may be communicated via the internet in cases where the structure or object is an IoT device.

The optimization process may involve modeling the structure with Finite Element Analysis using standard finite elements such as truss, plate, solid, shell, or other elements. The optimization can aim to minimize structural weight or resource usage, subject to various constraints including stress, buckling, deflection, natural frequency, thermal considerations, fluid considerations, balance, leverage, system performance, robustness, resilience, and other constraints known in structural or engineering design optimization.

The present invention also encompasses a system for optimizing an engineering design. This system is composed of an Artificial Intelligence (AI) system that proposes an initial engineering design, and a numerical design optimizer that refines this initial design into an optimal engineering design. The optimal design is realized as a real-world, constructed object. The system includes the capacity to gather both real-world data from the constructed optimal engineering design and computed data generated from or during the optimization process. Furthermore, the system features a subsystem dedicated to training the AI based on some or all of the real-world data and/or computed data, facilitating the continuous enhancement of the AI's design capabilities.

The present invention also encompasses a system for optimizing a structural engineering design. It includes an AI system to propose an initial structural engineering design; a numerical structural design optimizer that optimizes the initial structural engineering design into an optimal structural engineering design; a real-world construction based on the optimal structural engineering design; real-world data from the real-world construction based on the optimal structural engineering design; computed data generated from the numerical structural optimizer concerning the optimized structural engineering design; and a subsystem to train the AI system on at least one of the real-world data and the AI system on the computed data.

While the Summary section outlines key features and examples of the invention, it should be noted that the invention is not restricted to these specific embodiments or examples. In addition to the specific combinations of features mentioned above, the present application discloses various other combinations and options. The invention further includes combinations of features not specifically identified as an example herein, thereby providing a wide range of possibilities for optimizing the design of structures and engineering designs.

The foregoing and other objects, features, and advantages of the invention will become more apparent from the following detailed description, which proceeds with reference to the accompanying figures.

### BRIEF DESCRIPTION OF THE DRAWINGS

FIG. 1 is a flowchart illustrating a method for optimizing the design of a structure, according to some embodiments of the present disclosure.

FIG. 2 is a flowchart illustrating a method for optimizing an engineering design, according to some embodiments of the present disclosure.

FIG. 3 is a flowchart illustrating a method of constructing a shape-optimized truss structure, according to some embodiments of the present disclosure.

FIG. 4 is a flowchart illustrating a method of constructing an optimized engineering design, according to some embodiments of the present disclosure.

FIG. 5 is a block diagram illustrating a system, according to some embodiments of the present disclosure.

### DETAILED DESCRIPTION OF A PREFERRED EMBODIMENT

Considering Generative AI refers to a type of artificial intelligence that uses machine learning models to generate new content that mimics or resembles the data it was trained on. In the context of structural design, generative AI can be used to propose initial or novel designs based on the criteria input into the system.

Generative AI can work in concert with traditional structural optimization technology to generate and optimize structural designs, potentially saving time and resources compared to traditional design methods.

Structural Optimization is iterative. Consequently, the initial designs proposed by the generative AI serve as a starting point for further optimization. The generative model can continue to refine the designs in an iterative process, proposing slight modifications and using the input criteria to evaluate and improve upon the design. The AI can also propose multiple starting designs, so that a user may choose one. Or, multiple structural optimizations may be run, each with a different initial design, some or all of which the AI has proposed, or some or all of which the user has proposed, or a mix of the two. Running optimizations from more than one initial design may result in different optimal designs, and the best or most suitable optimal design for the purpose may be chosen.

In one embodiment, a generative model is trained with information about the mechanical, structural, or other design that will be optimized. Using the trained generative model, one or more potential new starting designs are generated. To set up the optimization, an objective function is identified, such as minimizing weight or maximizing strength or other desired outcome. Constraints on the objective function, sometimes relating to criteria that the optimized design must have, are formulated.

Numerical optimization is then used to refine the initial design(s) by finding the one(s) that best optimize the objective function while also satisfying the constraints. This makes one or more “optimal designs.”

In one embodiment, the optimized design or a design similar to it are constructed in the real world. The real-world design is tested and/or data generated from it. This real-world data is then used to further train the generative AI model.

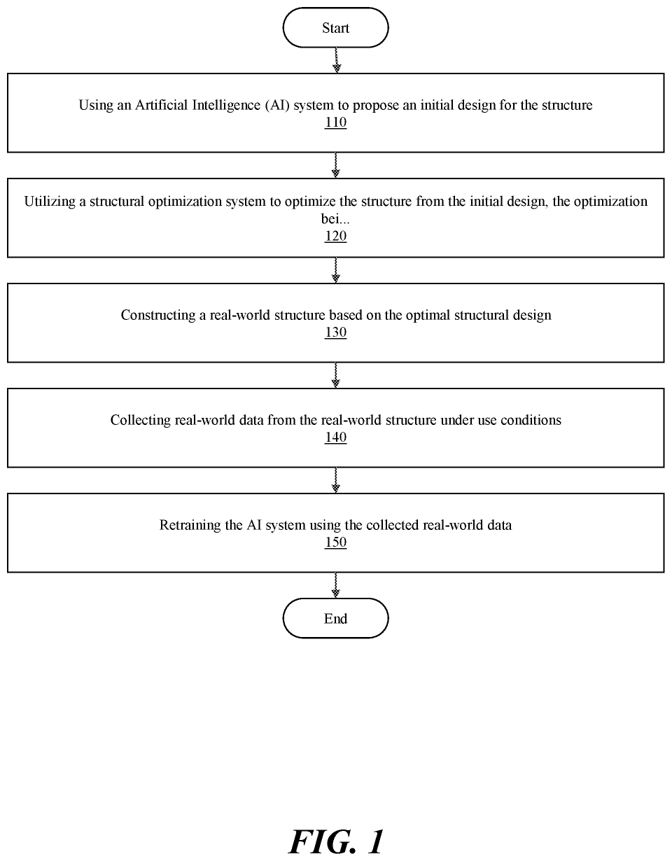

Considering now non-limiting examples, FIG. 1 is a flowchart that describes a method for optimizing the design of a structure, according to some embodiments of the present disclosure. In some embodiments, at 110, the method may include using an Artificial Intelligence (AI) system to propose an initial design for the structure. At 120, the method may include utilizing a structural optimization system to optimize the structure from the initial design, the optimization being an iterative process to reach an optimal structural design that maximizes or minimizes a property subject to at least one constraint. At 130, the method may include constructing a real-world structure based on the optimal structural design. At 140, the method may include collecting real-world data from the real-world structure under use conditions. At 150, the method may include retraining the AI system using the collected real-world data.

In some embodiments, the structure may be at least a component of a biomedical device. In some embodiments, the structure may be at least a component of a cardiac device. In some embodiments, the method may include implanting the biomedical device into a human or animal body. In some embodiments, 3D printing the real-world structure. In some embodiments, the real-world structure may be a scale model of the optimal structural design.

In some embodiments, the real-world structure may be a component of an Internet of Things (IOT) device. In some embodiments, the step of collecting real-world data from the real-world structure under use conditions further comprises communicating real-world data via the internet. In some embodiments, the step of constructing a real-world structure based on the optimal structural design may include incorporating into or attaching to the real-world structure at least one RFID tag.

In some embodiments, the structure may be a civil structure. In some embodiments, the structure may be an antenna for tracking animals. In some embodiments, the structure may be a hand tool used while constructing a building. In some embodiments, the structure may be a trailer for transporting a vehicle. In some embodiments, during the optimization process, the structure may be modeled with Finite Element Analysis using one or more standard finite elements.

In some embodiments, the standard finite elements may include truss, plate, solid, shell, or other standard finite elements. In some embodiments, the optimization may minimize structural weight, subject to constraints comprising at least one of stress, buckling, deflection, natural frequency, thermal considerations, fluid considerations, balance, leverage and/or other constraints known to be used in structural optimization. In some embodiments, the optimization may be topology optimization. In some embodiments, the real-world structure may include one or more RFID tags. In some embodiments, the real-world structure may be an Internet of Things (IoT) device. In some embodiments, the AI system may comprise Generative Design Artificial Intelligence.

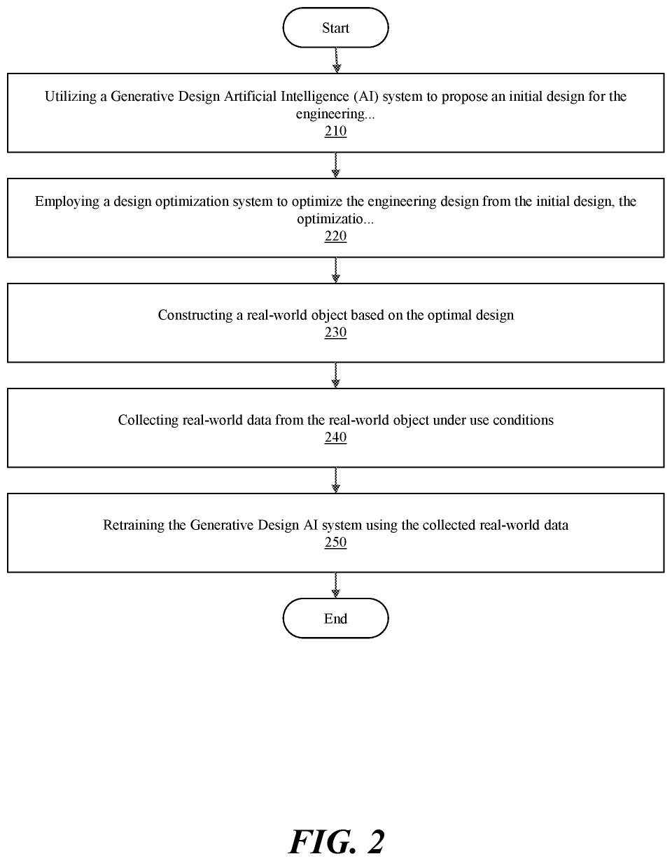

FIG. 2 is a flowchart that describes a method for optimizing an engineering design, according to some embodiments of the present disclosure. In some embodiments, at 210, the method may include utilizing a Generative Design Artificial Intelligence (AI) system to propose an initial design for the engineering design. At 220, the method may include employing a design optimization system to optimize the engineering design from the initial design, the optimization being an iterative process that uses computational modeling to reach an optimal design that maximizes or minimizes a property subject to at least one constraint. At 230, the method may include constructing a real-world object based on the optimal design. At 240, the method may include collecting real-world data from the real-world object under use conditions. At 250, the method may include retraining the Generative Design AI system using the collected real-world data.

In some embodiments, the method may include optimizing the shape of a structure. In some embodiments, the engineering design may be for a component of a civil infrastructure structure. In some embodiments, the engineering design may be for a structural component of a mechanical system. In some embodiments, the engineering design may be for an electronic device. In some embodiments, the optimization may minimize resource usage, subject to constraints on system performance, robustness, resilience and/or other constraints known to be used in engineering design optimization.

In some embodiments, the real-world object may include one or more sensors for collecting real-world data. In some embodiments, the real-world object may be an Internet of Things (IoT) device. The method may include transmitting the real-world data via the Internet. In some embodiments, the method may include optimizing a performance characteristic of a replacement heart valve. In some embodiments, the step of training the generative AI on the collected real-life data further comprises training the generative AI such that the model may be trained for one or more specific users, use cases, or locales.

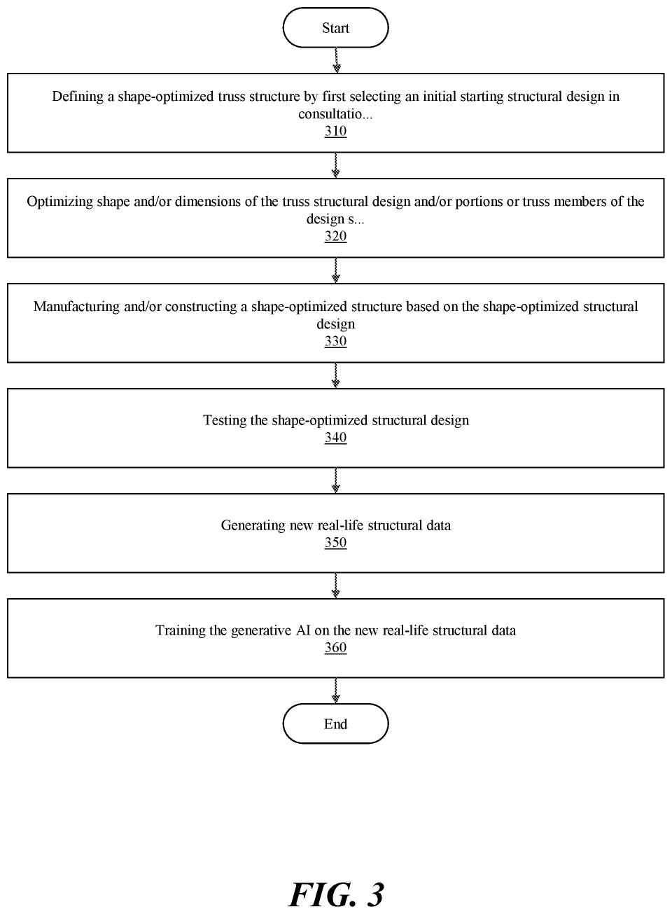

FIG. 3 is a flowchart that describes a method of constructing a shape-optimized truss structure, according to some embodiments of the present disclosure. In some embodiments, at 310, the method may include defining a shape-optimized truss structure by first selecting an initial starting structural design in consultation with generative artificial intelligence. At 320, the method may include optimizing shape and/or dimensions of the truss structural design and/or portions or truss members of the design subject to pre-defined constraints using a numerical structural design optimization technique to create a shape-optimized structural design. At 330, the method may include manufacturing and/or constructing a shape-optimized structure based on the shape-optimized structural design. At 340, the method may include testing the shape-optimized structural design. At 350, the method may include generating new real-life structural data. At 360, the method may include training the generative AI on the new real-life structural data. The method may include the steps 310 to 360.

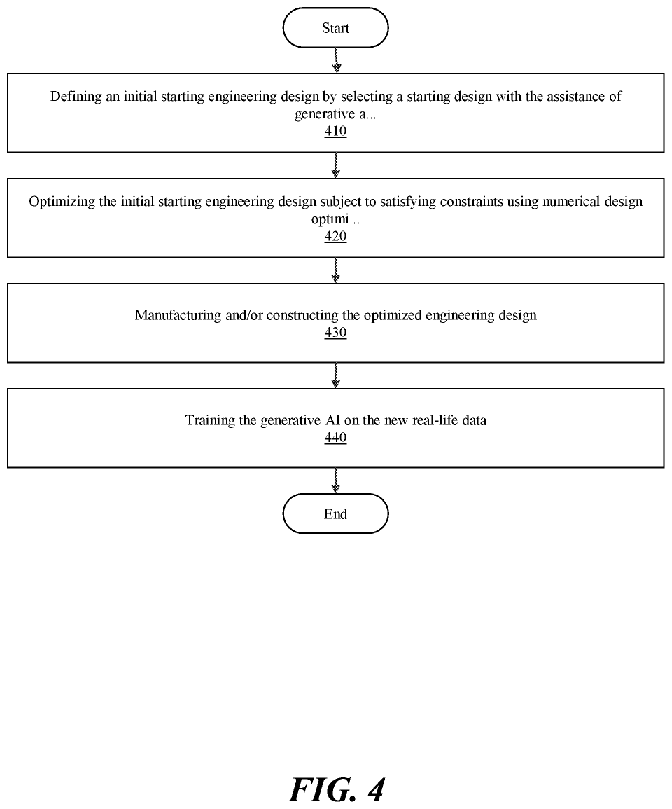

FIG. 4 is a flowchart that describes a method of constructing an optimized engineering design, according to some embodiments of the present disclosure. In some embodiments, at 410, the method may include defining an initial starting engineering design by selecting a starting design with the assistance of generative artificial intelligence. At 420, the method may include optimizing the initial starting engineering design subject to satisfying constraints using numerical design optimization to create at least one optimized engineering design. At 430, the method may include manufacturing and/or constructing the optimized engineering design. At 440, the method may include training the generative AI on the new real-life data. The steps of, the method may include 410 to 440. Testing or using the optimized engineering design and gathering real-life data about it. In some embodiments, the step of training the generative AI on the new real-life data further comprises training the generative AI such that the model may be trained for one or more specific users, use cases, or locales.

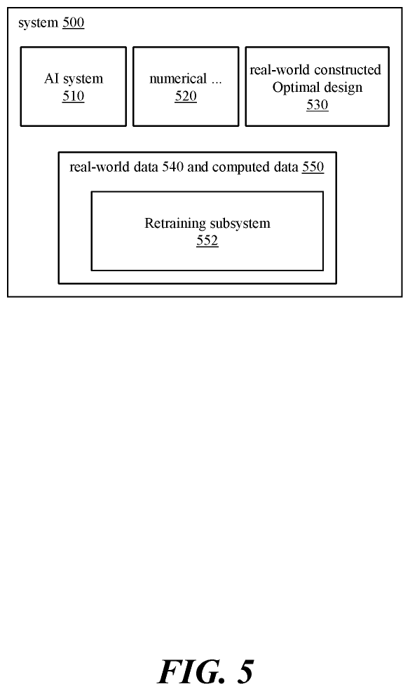

FIG. 5 is a block diagram that describes a system 500, according to some embodiments of the present disclosure. In some embodiments, the system 500 may include an AI system 510 to propose an initial engineering design, a numerical design optimizer 520 that optimizes the initial engineering design into an optimal engineering design, and a subsystem 540 to train the AI system 510 on at least some of at least one of the real-world data and computed data. The system 500 may also include a real-world 530, constructed optimal engineering design. At least one of real-world data from the constructed optimal engineering design and computed data generated from or during the optimization process of the optimized engineering design.

### Modeling Structures

In one embodiment, the structures to be optimized will be modeled with Finite Element Analysis (FEA). A user and/or the Finite Element package defines a structure with multiple finite elements to create a model of the structure. Then various types of analysis may be run on the model.

There are multiple types of finite elements. A structure may be modeled with just one type of finite element, or with multiple types of elements. A structure may be, for example, designed with multiple materials and/or member types, which may be considered in choosing which finite elements to use. The type of element used hinges on the specific characteristics of the structure and the nature of the analysis required. Some of the elements include:

Linear Elements: Linear elements, also known as 1D elements, are typically employed in the modeling of elongated, slender structures with consistent cross-sectional profiles. Examples of such structures include architectural trusses in building design, the supporting beams in bridge construction, and the elongated shafts found in many types of machinery.

Planar Elements: Planar elements, or 2D elements, find their application in the modeling of structures with a consistent cross-sectional profile along a certain axis. These are often used in the analysis of thin plates, slabs, or walls that are part of larger structural assemblies, such as the wings of an airplane, walls of a dam, or the surface of a road.

Solid Elements: Solid elements, or 3D elements, are quintessential in the modeling of complex structures where a 1D or 2D approximation would fall short in capturing the full detail of the physical behavior. Examples include the stress analysis of a solid turbine blade, the thermal analysis of an engine block, or the detailed structural analysis of a complex joint or connection in a larger assembly.

Shell Elements: Shell elements are employed in modeling thin, plate-like structures where the thickness is small compared to the other two dimensions. Shell elements are used extensively in the analysis of automotive body parts, aircraft fuselage, or the hull of a ship, where the thickness is often much smaller than the length and width.

Special Elements: Special elements are used for specific scenarios that cannot be accurately modeled by the other types of elements. For instance, gap elements are used in contact analysis for things like gear teeth interaction or ball bearing races. Mass elements are used in dynamic analysis for modeling parts of a structure with significant mass but without a clear geometric form, such as an engine on an aircraft wing. Spring elements are used to represent spring-like behavior, such as the suspension system in a vehicle.

Finite Element Analysis (FEA) is an indispensable tool in engineering and physics that allows for comprehensive analysis of complex systems. It is capable of assessing a multitude of parameters and phenomena, including but not limited to:

Stress Analysis: FEA is frequently used to analyze the distribution and magnitude of stresses within a structure subjected to external forces. This allows for the identification of stress concentrations, potential points of failure, and necessary design modifications. Stress analysis could be employed in the aeronautic industry, where the fuselage of an aircraft requires rigorous scrutiny to guarantee its structural integrity under flight and atmospheric conditions.

Strain and Deformation: FEA can compute the strain and deformation a structure will undergo under specific loads. This aids in understanding how a structure will behave in real-world conditions, ensuring it meets performance criteria and withstands intended loads. For infrastructural constructs such as bridges, an analysis of strain and deformation would be pivotal. For instance, the supporting pillars of a suspension bridge would necessitate an investigation to ascertain the bridge's capacity to bear both its inherent weight and additional loads, such as vehicular traffic, wind forces, and potential seismic activity.

Modal Analysis: This involves determining the natural frequencies and mode shapes of a system. These characteristics are crucial in many engineering domains to prevent resonance and potential failure. In the automotive industry, modal analysis plays a crucial role in ensuring operational safety and performance. The intricate components of a car engine, for example, must be confirmed to operate without resonating at the system's operational frequencies, which could precipitate damaging and potentially catastrophic vibrations.

Thermal Analysis: FEA is employed to study temperature distribution within a system subjected to thermal loads. It can predict how the heat will be distributed, the rate of heat transfer, and any resultant thermal stresses or deformations. The aerospace industry often requires the implementation of thermal analysis. A salient example is the heat shield on a spacecraft, which must be rigorously tested to ensure its capacity to withstand and effectively dissipate the extreme heat generated during atmospheric re-entry.

Fluid Dynamics: FEA can be used in conjunction with Computational Fluid Dynamics (CFD) to analyze fluid flow, pressure distribution, and fluid-structure interactions. In naval architecture, the hull of a ship would be analyzed using principles of fluid dynamics. This analysis enables the prediction of the ship's interaction with water, which includes parameters such as hydrodynamic efficiency and stability under various sea conditions.

Electromagnetic Analysis: In electronics and electrical engineering, FEA is used to study the behavior of electromagnetic fields and their effects on and interactions with materials and circuits. For electrical systems, electromagnetic analysis is of paramount importance. For instance, the casing of an electrical transformer might undergo such an analysis to guarantee the proper containment of the electromagnetic field and to mitigate potential risks associated with its leakage.

Buckling Analysis: FEA aids in predicting the buckling load of a structure, an essential consideration in the design of slender structures subject to compressive loads. In civil engineering, particularly in the construction of high-rise structures, buckling analysis is fundamental. The supporting columns of a skyscraper, for example, must be analyzed for potential buckling to ensure they can support the building's weight and withstand lateral wind forces.

Fatigue Analysis: FEA can be utilized to estimate the life of a structure subjected to cyclic loads, helping to predict when and where fatigue failure may occur. Fatigue analysis is particularly relevant to structures subjected to cyclic loads. Wind turbine blades, subject to recurrent and fluctuating wind loads, would undergo fatigue analysis to predict their lifespan and operational efficiency over time.

Contact Analysis: This type of analysis is used to simulate the interaction between components in contact with each other, considering factors such as friction, contact pressure, and deformation at the contact interface. In mechanical systems with interacting components, contact analysis proves useful. Consider the gears in a mechanical watch; a contact analysis would help understand the interaction, potential wear, and overall performance optimization.

The specific non-limiting examples identified above for each of the analysis types are merely examples for the purpose of illustration, and there are many other applications of each type of analysis. By simulating scenarios such as this, FEA offers invaluable insights into the performance of structures, components, and materials under a variety of conditions, aiding in the optimization of design and the mitigation of potential issues prior to or in conjunction with physical testing or production.

In inventor Scott Hansen's own research with Vanderplaats, as cited above for example, his focus was on structural analysis of stress, displacement, buckling, and modal analysis. From this analysis, the numerical optimizer used data to calculate dimensions and/or shape of a proposed optimal design. FEA analysis of the proposed optimal design was then done, and the numerical optimizer would use this new FEA analysis to propose yet another optimal design. This cycle would continue until the proposed optimal designs “converged.” That is, the shape and/or dimensions of the proposed optimal designs became consistent from cycle to cycle, changing very little or not at all with each successive cycle. To make the process more efficient, Hansen incorporated linear approximations of force in the structure, for example.

However, it should be understood that FEA can model a structure to calculate a wide variety of performance characteristics, as exemplified by the list above, for example. Each of these analysis types, when employed effectively, equips engineers and designers with predictive insights into the performance of structures and systems under diverse conditions.

It should also be understood that structural optimization is only one type of optimization to which the present invention applies. Numerical optimization techniques can be applied to a wide variety of engineering and scientific systems and devices that are not structures, or that are a mix of structural and non-structural components. Analyzing such systems and devices may be done with techniques and models other than finite element analysis, and finite element analysis is given here as a non-limiting example of an analysis tool that may be used in the iterative numerical design process.

As non-limiting examples of analysis other than FEA that can be used in a numerical design optimization process:

Boundary Element Method (BEM): This numerical computational method is often applied in engineering and mathematical physics for solving linear partial differential equations. For instance, BEM has been utilized in acoustics to predict sound fields both interior and exterior to structures, such as the acoustic properties within an auditorium or noise emission from vehicles.

Monte Carlo Simulation (MCS): This statistical technique is used to understand the impact of risk and uncertainty in prediction and forecasting models. It has found wide-ranging applications, such as in financial engineering for pricing complex derivatives, or in project management to anticipate potential delays and cost overruns.

Computational Fluid Dynamics (CFD): This branch of fluid mechanics uses numerical analysis and algorithms to solve and analyze fluid flows. Applications are extensive, including predicting airflow over aircraft wings for aerodynamic optimization, or simulating the flow of blood in the cardiovascular system for medical device design.

Multi-body Dynamics (MBD): This method is used to describe the motion of assemblies of interconnected bodies under the action of external forces. In the automotive industry, for example, MBD is used to simulate and optimize the dynamic behavior of vehicles during maneuvers.

Lattice Boltzmann Method (LBM): This is a computational fluid dynamics method for simulating fluid flows using a lattice grid. It has been used, for instance, in the analysis of complex porous structures, such as understanding fluid flow in oil reservoirs.

Finite Difference Method (FDM): This numerical method is used to solve differential equations by approximating them with difference equations. Applications include the simulation of heat transfer in solids, or solving Schrödinger's equation in quantum mechanics.

Finite Volume Method (FVM): This method is commonly used in CFD to convert the partial differential equations representing conservation laws over differential volumes into discrete algebraic equations over finite volumes. It is employed in a wide range of applications, such as simulating climate models or combustion within engines.

Discrete Element Method (DEM): This is a numerical technique that allows for the detailed analysis of granular materials and many other complex systems. For example, it is used in the design and optimization of industrial equipment for handling and processing granular materials, like in mining or pharmaceutical industries.

These computational techniques, among others, offer engineers, scientists, and researchers tools for optimizing designs and improving the understanding of various physical phenomena. Embodiments incorporation one or more of these techniques fall within the scope of the present invention. Again, this list is by way of non-limiting example.

### Generative AI in Structural Engineering

Key steps in implementing generative AI for structural design include:

Data Collection and Preparation: Before generative AI can suggest a design, it needs to be trained on a dataset of structural designs and their associated performance metrics. This could include data on different materials, shapes, dimensions, and other factors that contribute to the performance and functionality of a structure. It can take into account optimized structures that structural optimization analysis have designed, knowing as well the constraints (maximum stress, deflection, natural frequencies, etc.) under which the optimized structures are designed.

Model Training: This data is used to train a machine learning model. The model learns to understand the relationships between different design elements and their impact on the performance of the structure. For example, it might learn that certain materials or shapes lead to more durable or efficient structures under specific conditions. As noted, model training might initially be with synthetic data. But the model can be improved over time, or localized for a particular use or user, by constructing a structure or scale model of the structure with configuration and/or dimensions suggested by a structural optimization analysis, then gathering real-world data about the performance of the real-world structure, taking into account real-world factors and variables that the structural optimization analysis might not consider.

Design Generation: Once the model is trained, it can be used to generate new designs. When you input specific criteria (such as desired performance metrics, material constraints, environmental conditions, etc.) into the generative AI platform, the model uses what it has learned to propose a design that it predicts will meet those criteria. This is often done through a process of probabilistic sampling, where the model generates a range of possible design solutions and selects the ones that best meet the input criteria. As noted, the model can be retrained over time with data generated during the structural optimization analysis and/or with real-world data gathered from real-world structures.

### Applications of Generative AI in Engineering Design

Considering applications of generative AI in engineering design more broadly, generative AI can be used in a number of ways to improve engineering design processes. Here are some potential applications:

Generative Design: Generative AI can be used to create a large number of design alternatives based on certain constraints and objectives. This is a powerful tool for engineers, as it allows them to explore the design space more thoroughly than would be possible manually.

Optimization of Existing Designs: By learning from a large database of existing designs, generative AI can propose improvements and optimizations to these designs. For example, it can suggest ways to reduce material usage while maintaining strength and functionality.

Design of Complex Systems: Generative AI can be used to design complex systems, such as electrical circuits or mechanical assemblies. By learning from examples, the AI can generate new designs that meet specified criteria.

Material Design: Generative AI can be used to propose new materials with desired properties. By learning from a database of existing materials and their properties, the AI can suggest new combinations of elements and compounds.

Predictive Maintenance: By learning from operational data, generative AI can predict when parts or systems might fail and suggest design modifications to improve reliability.

Prototyping and Simulation: Generative AI can be used to generate realistic prototypes and simulations of designs. This allows engineers to test and refine their designs more quickly and accurately.

Customization: Generative AI can be used to create custom designs that are tailored to specific users or use cases. For example, it could be used to design custom-fit clothing or prosthetics.

Knowledge Extraction: Generative AI can help in extracting useful design patterns or strategies from existing design data, helping designers and engineers to improve their design process based on learned best practices.

High-quality data for training, a well-defined problem scope, and appropriate AI model selection and tuning are important.

### Some Applications of Numerical Optimization in the Automotive Industry

Turning now to specific applications of numerical optimization, to which as this application proposes can be coupled with generative AI, examples of applications in which the invention may be used can include:

Vehicle Chassis: Optimization of chassis designs for weight reduction, improved stiffness, and better crashworthiness.

Suspension Systems: Optimization of suspension components, such as springs, dampers, and control arms, for improved handling, ride comfort, and reduced weight.

Engine Design: Optimization of engine components, like pistons, crankshafts, and cylinder heads, for increased power, fuel efficiency, and reduced emissions.

Transmission Systems: Optimization of gear ratios and shift schedules for better fuel efficiency, performance, and drivability.

Aerodynamics: Optimization of vehicle body shapes and aerodynamic add-ons, like spoilers and air dams, to minimize drag and enhance fuel efficiency.

Exhaust Systems: Optimization of exhaust system components, such as catalytic converters and mufflers, for reduced emissions and improved performance.

Thermal Management: Optimization of cooling systems, including radiators and heat exchangers, for efficient heat transfer and reduced weight.

Braking Systems: Optimization of brake components, such as rotors, calipers, and pads, for better braking performance, reduced weight, and longer service life.

Electric and Hybrid Systems: Optimization of battery packs, electric motor designs, and power electronics for enhanced efficiency, range, and performance in electric and hybrid vehicles.

Structural Components: Optimization of various structural components, like door panels, pillars, and roof structures, for improved safety, reduced weight, and enhanced manufacturing feasibility.

Noise, Vibration, and Harshness (NVH): Optimization of vehicle designs to minimize unwanted noise, vibrations, and harshness, leading to a more comfortable driving experience.

### Some Examples of Numerical Optimization in Aerospace

Numerical design optimization techniques have been extensively applied in the aerospace industry to improve a variety of aircraft and spacecraft components and systems. Here are some specific examples:

Wing Design: Optimization of wing shape and structure for improved lift-to-drag ratio, weight reduction, and fuel efficiency.

Fuselage Design: Optimization of fuselage structures for weight reduction, improved aerodynamics, and passenger comfort.

Engine Design: Optimization of jet engine components, like turbine blades, combustion chambers, and nozzles for increased thrust, fuel efficiency, and reduced emissions.

Propeller Design: Optimization of propeller shapes and materials for improved efficiency, reduced noise, and longer service life.

Structural Components: Optimization of various structural components, such as ribs, spars, and stringers, for weight reduction and improved structural integrity.

Aircraft Layout: Optimization of aircraft layout, including passenger seating, cargo space, and fuel tanks for maximum utilization and safety.

Control Systems: Optimization of control systems for improved stability, maneuverability, and efficiency.

Spacecraft Design: Optimization of spacecraft components, like solar panels, antennas, and thermal protection systems for enhanced functionality and longevity in space.

Trajectory Optimization: Optimization of flight and launch trajectories for reduced fuel consumption and improved mission success rate.

Material Selection: Optimization of material selection for different components considering weight, strength, cost, and thermal properties.

Aircraft Landing Gear: Optimization of landing gear design for improved strength, reduced weight, and better shock absorption.

Noise Reduction: Optimization of various components and their arrangement for noise reduction, improving passenger comfort and meeting environmental regulations.

Manufacturing Processes: Optimization of manufacturing processes, like machining and 3D printing, for cost reduction, improved accuracy, and reduced production time.

In each of these cases, the optimization process starts from an initial design, then iteratively changes the design to reach an optimal design under the constraints the user defines. Generative AI as proposed herein can be trained to propose initial designs that the optimization routines then optimize.

### Further Examples of Structural Optimization Applications

Numerical structural optimization has been used in various fields, such as aerospace, automotive, civil engineering, and product design. The present invention relates to using AI to propose initial designs for the optimization process. Some examples of structural engineering applications to which optimization has been utilized, and to which the present invention may be applied, include:

Aerospace Engineering: In the design of aircraft and spacecraft, numerical structural optimization is used to minimize the weight of the structure while ensuring that it can withstand the stresses it will be subjected to. For example, this has been applied to optimize the design of wings, fuselage structures, and landing gear.

Automotive Engineering: In the automotive industry, numerical structural optimization has been used to design components like chassis, car bodies, and suspension systems. The goal is usually to minimize weight (for fuel efficiency) and material usage (for cost), while ensuring safety (withstanding crash scenarios, for example).

Civil Engineering: In civil engineering, this technique has been applied to optimize the design of structures such as bridges, buildings, and dams. The goal is often to minimize the cost or use of materials while ensuring the structure can withstand various loads (such as wind, earthquakes, and the weight of the structure itself).

Energy Industry: In wind turbine design, structural optimization has been used to design turbine blades that are light, strong, and efficient. This can result in more efficient energy production.

Product Design: In consumer products, numerical structural optimization can be used to design products that are durable, lightweight, and use materials efficiently. This can be applied to a wide range of products, from furniture to electronics.

Biomedical Engineering: In the design of medical implants and prosthetics, numerical optimization can be used to design structures that mimic and/or incorporate the mechanical properties of biological tissues, leading to better patient outcomes.

Shipbuilding: In the marine industry, structural optimization has been applied to design ships' hulls and other components to minimize weight and maximize strength and durability.

Manufacturing: In manufacturing processes, optimization techniques can be used to design tools and machinery that are efficient and durable.

Architectural Engineering: In the design of complex architectural forms, numerical optimization can be used to find structural solutions that are both aesthetically pleasing and structurally sound.

In all these cases, numerical structural optimization involves creating a mathematical model of the structure, defining an objective function (such as minimizing weight or cost), defining constraints (such as maximum allowable stress), and using an optimization algorithm to find the best design.

### Some Further Examples of Applications of Numerical Optimization

Considering alternative applications of embodiments of the present invention that may optimize systems including components beyond the scope of purely mechanical structural design, the concept of generating initial designs for the optimization process using AI, then refining the AI model with real-world data and/or from data generated by the optimization analysis, may include, for example:

Supply Chain Optimization: In industrial engineering, numerical optimization is used to optimize supply chains, including scheduling, routing, inventory management, and logistics.

Power Systems: In electrical engineering, numerical optimization is used for optimizing power generation and distribution, such as in the scheduling of power plants, load balancing, and renewable energy integration.

Process Engineering: In chemical and process engineering, numerical optimization can be used to optimize chemical reactions and processes for efficiency, yield, and quality control.

Control Systems: In systems engineering, numerical optimization is used in the design of control systems to improve stability, performance, and robustness.

Signal Processing: In communications engineering, numerical optimization is used in signal processing to improve the quality and reliability of communication signals.

Water Resource Management: In civil and environmental engineering, numerical optimization is used in water resource management for optimizing the allocation of water resources, scheduling of irrigation, and flood control.

Traffic Engineering: Optimization algorithms are used to optimize traffic signals and manage flow to minimize congestion and improve traffic conditions.

HVAC Systems: In mechanical and environmental engineering, numerical optimization is used to optimize the design and operation of heating, ventilation, and air conditioning (HVAC) systems for energy efficiency and comfort.

Biomedical Engineering: In the design of medical devices, like prosthetics and implants, or in the optimization of medical imaging techniques and radiation therapy planning.

Robotics: In robotics, numerical optimization is used in path planning, motion control, and kinematics.

Network Design: In telecommunications and computer networking, numerical optimization is used to design network topologies, routing, and resource allocation for optimal performance and reliability.

Antenna Design: Co-inventor Louisa Hansen has used antennas as part of a system to track rattlesnakes in the Illinois forest and fields, for example. Antennas are used in a range of contexts. It is proposed herein that numerical optimization techniques be employed to optimize antennas. This may include structural optimization and/or other numerical optimization. This may include, as examples only, Yagi antennas and coil antennas. Yagi antennas, for example, may be adapted for wildlife research tracking under demanding field conditions. Antennas might be optimized for best signal reception range, as well as for shape and structural performance, for example. Various related transmitters, for example, may be optimized.

Housing for Animals: Structures and/or systems relating to animals may be optimized. For example, a kennel, chicken coop, or other structure may be optimized. Similarly, our family member Professor Edwin L. Hansen, formerly engineering professor at University of Illinois, did extensive work in the design of hog houses, for examples, which have many aspects that may be optimized. His major research contributions concerned the development of concrete as a construction material in agricultural buildings. He also developed the concept of precast concrete components and concrete rigid frames. Hansen was a leader in confinement housing systems for swine, help-ing develop the “Hog-O-Matic,” a facility at the University's farms that featured automatic feeding and floor cleaning. It was equipped to feed the pigs and clean the floor under fully automatic control. Cleaning was done below with two jets of water under 70 pounds of pressure. The revolving boom circles a 21.5-foot exercise area every 2.5 minutes. A 4-inch center drain carried the wastes away. Hansen also developed systems for solar heating of hog houses. Optimization may be applied to automatic feeding structures and systems as well as to agricultural floor cleaning devices and systems, and other aspects of automated feeding and cleaning systems for raising animals.

Agricultural Equipment: Our family member Harold V. Hansen is inventor on various patents relating to agricultural equipment, many assigned to John Deere & Co. of Moline, Illinois. Examples include the following US patents, for example: U.S. Pat. Nos. 4,009,668, 3,552,601, 3,543,704, 3,511,319, 3,454,106, 3,478,828, 3,511,522, 2,919,078, 3,488,061, 2,962,103, 3,627,057, 3,075,790, 3,055,322, 2,975,841, 2,979,136, 3,019,032, 3,027,050, 2,906,436, 2,975,844, 2,784,883, 3,194,322, 3,038,425, 3,372,657, 3,373,705, 3,059,705, 2,828,679, 3,177,829, 2,833,440, 3,397,658, 2,859,678, 2,946,490, 3,158,115, 2,996,926, 3,079,174, 3,627,050, 3,626,877, 2,967,432, 3,166,204, all of which are incorporated by reference herein. There are numerous potential applications for numerical optimization of agricultural equipment, such as the design of blades, planting structures, tires, gears, fuel systems, motor components, and other devices, systems, and structures addressed in the foregoing patents.

Agricultural and Highway Sprayers: Our family member Charles K. Stralow is listed as inventor on patents relating to large agricultural sprayers and assigned to agricultural machinery company John Deere & Co., such as the following US patents, all of which are incorporated by reference herein: U.S. Pat. Nos. 3,236,456, 3,160,347, 3,231,198, 3,369,506. One of many aspects identified in these patents is a sprayer having a boom frame structure having upper and lower portions. Various structures, systems, and components relating to agricultural and highway sprayers may be optimized. Boom frames are just one example.

### Other Applications

Other applications of optimization include: aerodynamic shape optimization (wings, etc.), machine components (driveshafts, brakes, gears), heat exchangers, steam condensers, and aircraft and ship synthesis.

### Military and Hospital Systems

Our family member US Navy Commander Robert E. Hansen (ret.) is a former US Navy Seabee and hospital engineer. In his naval career, he participated in and led large construction projects globally. He also worked in the field of Navy public works, which typically includes constructing, developing, and managing facilities, roads, drinking water and sewage systems, and other civil engineering structures and systems. Later in his career he was a hospital engineer, leading teams relating to and overseeing hospital structures, power generation, medical devices, construction, and other physical aspects of hospitals and healthcare. Concerning optimization, structures relating to transporting and housing boats (trailers etc.), ships, submarines, construction equipment, and other naval civil and mechanical engineering-related structures may be optimized.

In the construction field, tools are important. Examples of tools that may be optimized are ladders (weight, stiffness, strength, torsion, balance, etc. are important), saws, scaffolding, power saws and other power tools (weight, balance), wheelbarrow (balance, weight, transmitting weight to wheel, etc.).

Hospital engineering includes, for example, devices and systems that have structural, fluid, and thermal aspects. For example, a whirlpool bath for rehabilitation and/or athletics includes a structure. And also fluid flow, heat transfer, insulation properties, among other things. A hot tub, generally, and other systems have a similar interaction of structural, thermal, fluidic, and/or other significant interacting influences on an optimal design.

In systems such as this, any of these aspects may be focused upon as the objective function, with other aspects treated as constraints, for example. The AI system might choose one initial design if the objective function relates to minimizing weight of the structure, whereas it might select a different starting design if the objective function is fluidic or thermal, for instance.

In military applications, boat trailers are an example of a structure that may be optimized. The trailer should be lightweight, but also strong (the cost of damage to a boat can be high if the trailer structure fails). As it is used on roads, there are vibration and stability considerations. There may be fluid flow aspects concerning drag caused as the trailer is pulled at speed. There may be thermal aspects such as when the trailer is out in the hot sun, or used on a cold winter day. With a heavy boat or other load on it, balance is also an important consideration. And possibly acoustic considerations if the trailer is used in stealthy operations in which quiet operation is desired.

HDD's: Hard disk drives are electro-mechanical devices using electromagnetics and/or other technologies to store data. Numerous components of HDD's may be optimized, including structural and other aspects. HDD's may be used as a single unit, in clusters, and even in large-scale data centers, all of which provide engineers with applications for optimization.

### Individualizing the AI System for Proposing Starting Designs

Considering our previous example further, an optimal boat trailer design in one region or for particular uses, might be different than an optimal boat trailer design in other regions or for different uses. Consequently, it can be helpful to “localize” an AI model for use by specific populations of users and by specific use cases and locales. This can be done, for instance, by having a local AI system proposing initial designs for one particular user or group of users, while proposing a different starting design for other users in other locations or operating conditions.

The “individualizing” may be triggered when the user enters certain information (e.g. the ZIP postal code in which the user operates, or other appropriate information for the purpose). Or it may be determined through data gathered from the optimized system or apparatus. For example, a user might provide the AI with a temperature range in which the trailer will be used or, alternatively, there may be sensors on a boat trailer logging the temperature over time so that the operating range may be determined through data from a sensor. Consequently, the AI system may take into consideration the particular use cases, locale, or other characteristics of a user in choosing a good initial design for that particular user or group of users. The AI system may be kept locally with the user, or it may be a unified AI system having many different users but tailoring its suggestions to each user depending on user profile, real-world data gathered from the user's systems and devices, or other information.

This concept of “individualizing” the AI model to suggest starting designs unique to particular users or groups of users may be applied generally to nearly all of the applications described in this patent application, as an optional feature. The individualization

### Retraining AI Systems

As noted, the optimization process starts with an initial design, then optimizes the design while satisfying constraints on the design. Once an optimal design has been reached, the process may further include:

Validation of the Solution: Validate the obtained solution. Check if the optimal solution satisfies all the constraints and truly optimizes the objective function. This could involve physical experiments, simulations, or other types of validation.

Implementation of the Optimal Design: After the optimization process, the optimal design parameters can be used to build the physical system or process.

Post-Optimization Analysis: Often, once the optimal design has been implemented, there may be a need for further analysis or testing. This could involve stress testing, reliability analysis, or even a new round of optimization if the system's performance still isn't satisfactory.

Once a physical version of the optimized design is built, data may be generated from it. For example, in the case of a civil structure, testing may include running tests on stress, deflection, natural frequency, and many other aspects. If desired, the design may be revised in light of the collected real-world data. The real-world data, the final design that the designers settle upon, revised optimal designs, and the like may be used to retrain the AI system. Thus, as the AI system is employed to propose initial designs in the future, it has the benefit of training on real-world data and experience.

Steps that may be used in retraining the AI initial design generation may begin with data collection. This first step involves gathering relevant data from real-world tests. This encompasses performance measurements under varying conditions, any encountered failures, and other significant observations. Following data collection, preprocessing is necessary to format the data for machine learning applications. This stage often includes cleaning the data, normalizing it, handling missing values, and formatting the data to match the input requirements of the generative design algorithm. With the preprocessed data, the generative design algorithm can be retrained. Depending on the specific algorithm used, this involves introducing the new data to the algorithm, which in turn adjusts its internal model accordingly. If employing a generative adversarial network (GAN), the new data would be input into the GAN, which subsequently trains to better generate designs that align with the updated data.

After retraining, the performance of the generative design algorithm may be evaluated. This could entail generating new designs and assessing how closely their performance matches the expectations based on the real-world test data. If performance falls short, alterations may be needed, such as tweaking the algorithm's parameters or gathering additional data.

The retrained generative design algorithm can then be used to generate novel initial designs. These can be further optimized, built, and tested in the real world. The data from these tests can be used to retrain the algorithm, creating a cyclical, iterative design process.

### AI Approaches

In one embodiment, Generative Design Algorithms are employed to generate initial designs. Generative Design Algorithms learn and understand patterns from existing design data. Upon gaining sufficient knowledge, they are capable of generating novel designs that adhere to these learned patterns. This technique offers a systematic approach to generating initial designs based on historical success.

Other AI approaches may alternatively be employed, such as:

Reinforcement Learning: This is a type of machine learning where an algorithm learns to make decisions by interacting with an environment. The algorithm improves iteratively, refining its decisions based on the feedback received from previous actions. In the context of design, reinforcement learning can be utilized to make a sequence of design decisions, progressively enhancing the quality of the design output.

Evolutionary Algorithms: These algorithms employ techniques such as mutation, crossover, and selection to find optimal or near-optimal solutions. Starting with a set of initial designs, evolutionary algorithms evaluate and refine these designs through iterative processes, eventually converging on a design that meets the set criteria for success.

Surrogate Modeling: Also known as metamodeling, this technique involves training a computationally efficient model to approximate the behavior of a more complex model. The surrogate model can rapidly evaluate a multitude of potential designs, thus providing a useful initial selection for further, more detailed analysis and optimization.

### CONCLUSION

While the inventive method and system are primarily detailed in the foregoing sections, it is important to underscore that various enhancements, alternatives, and modifications can be made to cater to different application-specific needs and contexts.

For instance, the application of one or more RFID tags to a physically optimized structure can provide valuable identification information about the structure. Multiple RFID tags can also be applied at disparate locations on the structure to identify different structural parts or regions. This localized RFID information can be used synergistically with data collected from specific members or areas of the structure, thereby providing a more granular level of data for retraining the AI system, leading to more precise and context-aware design iterations. RFID tags may assist with part identification and grouping as well as geometry feature recognition, for example.

Moreover, an optimized device or component can be integrated into the Internet-of-Things (IoT) ecosystem. This IoT-enabled structure can transmit real-world data over the internet, which can be harnessed for retraining the AI system or utilized for other beneficial purposes, such as predictive maintenance, remote monitoring, and dynamic performance adjustment.

Other areas in which numerical optimization with initial designs proposed by AI include: autonomous delivery vehicles and systems, green technology systems, solar panels, and structural components of power grids. In one optional approach, the AI may be developed with a no-code AI. Embodiments of the invention may include incorporating blockchain technology and/or using non-fungible tokens (NFTs). Digital twins, which are virtual simulations of real-world processes, operations, or products, may be used to develop new engineering designs in a digital environment. During development, 3D printing technology or other rapid prototyping approaches are used to create the items in the real world. To quickly solve very large engineering design optimization problems, quantum computers may be employed.

In certain scenarios, the cost implications of constructing an optimized structure, collecting real-world data, retraining the AI, and rebuilding a new optimized structure can be substantial. To circumvent such cost-related constraints, a cost-effective physical model of an optimized structure can be constructed, such as via 3D printing or other rapid prototyping techniques. Data gathered from these scaled-down models can be leveraged to retrain the AI system, allowing for multiple design iterations before the final, more expensive structure is built. For instance, in biomedical engineering, a 3D-printed model of a replacement heart valve can be used to conduct preliminary tests, enabling the refinement of the design before moving to traditional, more expensive manufacturing methods.

Considering further options, the AI system could consider manufacturing constraints in the design optimization process. This would ensure that the designs proposed by the AI system are not only optimal in terms of their intended function, but also feasible to manufacture. As another option, the AI system could be programmed to consider ethical and environmental factors in its design process. For instance, it could prioritize designs that use environmentally friendly materials or processes, or it could ensure that designs comply with ethical guidelines. The current invention may, in some embodiments, be employed in the design of nanostructures or nanomachines.

The present invention may, in some embodiments, may be implemented on or for display on Virtual Reality (VR) and/or Augmented Reality (AR) platforms.

Another option is to use multi-objective optimization, for simultaneous optimization of multiple objectives. Example: minimize structural weight while maximizing strength, with both being an objective, rather than just one as an objective and the other a constraint. The system may be adapted to list more than one possible optimal solution, in order to represent the trade-offs between the different objectives. AI may assist with the potential complexity of multi-objective optimization, and may help with presenting a user with multiple options and explanations of the potential pros and cons of different options, as AI can do with single objective optimization.

The invention can be extended to other systems where AI is trained with real-world data. An AI system initially trained with synthetic data can be progressively enriched with real-world data from prototypes, scale models, or even final engineering designs. This dual-training approach allows for the AI to continually improve its assistance to the engineering design team as it learns from real-world data.

Additionally, the optimization process can generate a wealth of data, such as sensitivity of a design to changes, finite element or other types of analysis calculations, gradients, iteration counts, fluid flow calculations, heat transfer analysis, and so on. This computed data, generated during the iterative numerical optimization process, can be used to train the AI system. Over time, this iterative learning process enhances the AI system's capacity to propose optimal designs early in the design process. By providing the AI system with details about the desired design, parameters, objective functions, constraints, and the like, the AI system can propose an optimal design that is likely to be more advanced and efficient than those it could predict when only trained with synthetic data.

In this context, we note different aspects of using the AI. One is AI System Training—The AI system is initially trained with synthetic or generated data. The system's performance improves as it gains more experience and ingests more data, including real-world data from physically optimized structures and computed data from the iterative numerical optimization process. Another is AI System Assistance—The AI system assists engineers and design teams by proposing initial designs and then refining these proposals based on optimization techniques and the newly gathered data. Still another is AI System Retraining—The AI system is retrained with new data. In the context of this passage, retraining involves updating the AI system with real-world data or computed data from optimization processes to refine its design proposals. There is AI System Learning—The AI system learns from the design process, improving its capacity to propose optimal designs early in the design process. These concepts may be interrelated in the context of some embodiments of the present disclosure.

We also note, for clarity, that the concept of “machine learning” is a subset of AI. Machine learning refers to the specific methodology where a system learns from data, improves its performance over time, and makes predictions or decisions without being explicitly programmed to perform the task.

In the context of the present invention, “AI” does not exclude “machine learning,” or vice versa. In some embodiments, machine learning may be used in the following context. “Machine Learning for Training” relates to when the AI system is initially trained with synthetic data or generated data, this is typically done using machine learning algorithms. These algorithms learn patterns from the input data and use these patterns to make predictions or decisions. “Machine Learning for Retraining” relates to retraining of the AI system with real-world data or computed data from the optimization processes can also be seen as a machine learning process. The system learns from new data, adjusts its internal model, and improves its performance. “Machine Learning for Proposing Designs” is when the AI system proposes initial designs and then refines these designs based on optimization techniques and newly gathered data, this process can involve machine learning. The system learns from the performance of past designs, applies this learning to propose new designs, and iteratively improves the design proposals over time. “Machine Learning for Continuous Improvement” is when the AI system's ability to improve its capacity to propose optimal designs early in the design process and is a hallmark of machine learning. The system learns from each design iteration, gradually improving its performance and ability to make accurate predictions.

So, in this context, machine learning can be seen as one method by which the AI system learns from data, makes predictions, and continuously improves its performance.

While the invention has been described in detail above with reference to preferred embodiments, it is understood that such details are solely for the purpose of illustration. It will be appreciated by those skilled in the art that variations in these details may be made without departing from the spirit and scope of the invention as defined by the appended claims.

Aspects of the invention may be modified, if necessary, to employ systems, circuits, and concepts of the various patents, applications, and publications to provide yet further embodiments of the invention. These and other changes can be made to the invention in light of the detailed description.

These and other modifications and variations to the present invention may also be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

As used herein, the term “upper” and “lower” are relative terms. For example, upper and lower portions of the clamshell unit may be side-by-side in some configurations. Consequently, “upper” and “lower” are not directionally limiting.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1-71. (canceled)

72-82. (canceled)

83. A method for optimizing the design of a simulated structure using an Artificial Intelligence (AI) system that has been trained with real-world data obtained from real-world physical structures built according to optimal designs optimized in simulated space, the method reducing differences between simulated structures optimized in simulated space and their optimal real-world physical structure counterparts, the method comprising the steps of:
a) initiating a structural optimization with a pre-optimization simulated structural design that a Generative AI system proposed;
b) After the step of initiating a structural optimization, utilizing a structural optimization system to optimize the simulated structure from the pre-optimization simulated structural design to reach an optimal simulated structural design that maximizes or minimizes weight of the simulated structure subject to at least one constraint from the group constituting deflection, stress, strain, buckling, fatigue, manufacturability, cost, and natural frequency;
c) After the step of utilizing a structural optimization system to optimize the simulated structure, constructing a physical structure that is a physical version of the optimal simulated structural design;
d) After the step of constructing a physical structure, collecting real-world data about the physical structure under real-world use conditions with sensors, including real-world data about at least one of: deflection, stress, strain, buckling, fatigue, manufacturability, cost, and natural frequency;
e) After the step of collecting real-world data, retraining the Generative AI system with the collected real world data to make a retrained Generative AI system;
f) After the step of retraining the Generative AI system with the collected real-world data, initiating a second structural optimization on a different, second structure with a second pre-optimization simulated structural design that the retrained Generative AI system generated; and
g) repeating steps a)-f) with a plurality of additional structural optimizations in order to reduce differences between simulated optimal structures optimized in simulated space and their real-world optimal physical structure counterparts.

84. The method of claim 83 wherein the AI system further comprises a Generative AI capability to facilitate creation of new content in response to a query from a user, the method further comprising creating new content in response to a query from the user.

85. The method of claim 84 wherein the Generative AI capability is a GPT.

86. The method of claim 84 wherein the query is about at least one of the pre-optimization simulated structural design, the optimal simulated structural design, the physical structure, and the real-world data collected from the physical structure.

87. The method of claim 84 wherein the new content is at least one of: images, music, voice, text, and data.

88. The method of claim 83, wherein the physical structure is a scale model of the optimal simulated structural design.

89. The method of claim 83, wherein the physical structure is an Internet of Things (IoT) device, and the step of collecting real-world data from the physical structure under real-world use conditions further comprises communicating the real-world data collected from the physical structure via the internet.

90. The method of claim 83, wherein the step of constructing a physical structure based on the optimal structural design includes incorporating into or attaching onto the real-world structure an RFID tag.

91. The method of claim 83, wherein the structure is an antenna for tracking animals.

92. The method of claim 83, wherein the structure is a hand tool used while constructing a building.

93. The method of claim 83, wherein the structure is a trailer for transporting a vehicle.

94. The method of claim 83, wherein during the optimization process, the structure is modeled with Finite Element Analysis using a plurality of standard finite elements.

95. The method of claim 83, wherein the method further comprises employing blockchain to enhance data integrity and traceability.

96. A method for optimizing an engineering design using a Generative Design Artificial Intelligence (Generative Design AI) system that improves itself over time to reduce differences between optimal designs in simulated space and optimal real-world designs, the method comprising the steps of:
Selecting a pre-optimization simulated engineering design from a plurality of proposed pre-optimization simulated engineering designs proposed by a Generative Design AI system.
Optimizing the pre-optimization simulated engineering design with an iterative numerical optimization process that uses computational modeling and a numerical optimizer to reach an optimal simulated design that maximizes or minimizes a property subject to at least one constraint;
After the step of optimizing the pre-optimization simulated engineering design, constructing a physical object based on the optimal simulated design
After the step of constructing a physical object, collecting real-world data about performance of the physical object under real-world use conditions;
Retraining the Generative Design AI system using the collected real-world data about performance of the physical object to make a retrained Generative Design AI system; and
After the step of retraining the Generative AI Design system, initiating an optimization on a different, second design with a second pre-optimization simulated design that the retrained Generative AI Design system generated.

97. The method of claim 96, wherein the Generative Design AI system facilitates creation of new content in response to a query from a human user, the method further comprising creating new content in response to a query from the human user.

98. The method of claim 97 wherein the query is about at least one of the pre-optimization simulated design, the optimal simulated design, the physical object, and the real-world data collected from the physical object.

99. The method of claim 98 wherein the new content is at least one of: images, sound, text, and data.

100. A method for optimizing a simulated engineering design using an Artificial Intelligence (AI) system that has been trained at least in part with real-world data obtained from real-world physical structures built according to optimal designs optimized in simulated space, the method reducing differences between simulated engineering designs optimized in simulated space and their optimal real-world physical structure counterparts, the method comprising:
Initiating a numerical design optimization with a pre-optimization simulated engineering design, the optimization using an engineering design analysis module;
After the step of initiating a numerical design optimization, utilizing an engineering design optimization system to optimize the simulated engineering design from the pre-optimization simulated engineering design to an optimal simulated engineering design that maximizes or minimizes an objective function subject to at least one engineering design constraint;
After the step of utilizing an engineering design optimization system to optimize the simulated engineering design, making a physical object that is a physical version of the optimal simulated engineering design;
After the step of making a physical object, collecting real-world data under real-world use conditions from the physical object with sensors;
After the step of collecting real-world data, retraining the AI system with the collected real-world data to make a retrained AI system, wherein this retraining step reduces differences between optimal engineering designs determined in simulated space and corresponding optimal real world engineering designs;
wherein the AI system further comprises a Generative AI capability to facilitate creation of new content in response to a query from a human user, the method further comprising creating new content in response to a query from the human user;
wherein the query is about at least one of: the pre-optimization engineering design, the optimal simulated engineering design, the physical object, and the real-world data collected from the physical object; and
wherein the new content is at least one of: images, sound, text, and data.

101. A method as defined in claim 100, wherein the method further includes minting an NFT from at least one of: the pre-optimization simulated engineering design, the optimal simulated engineering design, and the physical object.

102. A method as defined in claim 100, wherein the Generative AI capability is a GPT.

103. A method for optimizing the design of a simulated structure using a Generative Artificial Intelligence (AI) system that has been partially trained with real-world data obtained from real-world physical structures built according to optimal designs optimized in simulated space, the method reducing differences between simulated structures optimized in simulated space and their optimal real-world physical structure counterparts, the method comprising the steps of:
Initiating a structural optimization with a pre-optimization simulated structural design that a Generative AI system proposed, the structural optimization using a Finite Element Analysis structural model having a plurality of standard finite elements;
After the step of initiating a structural optimization, utilizing a structural optimization system to optimize the simulated structure from the pre-optimization simulated structural design to an optimal simulated structural design that maximizes or minimizes weight of the simulated structure subject to at least one constraint from the group constituting deflection, stress, strain, buckling, fatigue, manufacturability, cost, and natural frequency;
After the step of utilizing a structural optimization system to optimize the simulated structure, making a physical structure that is a physical version of the optimal simulated structural design;
After the step of making a physical structure, collecting real-world data with sensors from the physical structure under real-world use conditions, the real-world data including at least one of deflection, stress, strain, buckling, fatigue, manufacturability, cost, and natural frequency;
After the step of collecting real-world data, retraining the AI system with the collected real-world data to retrain the Generative AI system in order to reduce differences between optimal structural designs determined in simulated space and corresponding optimal real world structural designs; and
After the step of retraining the Generative AI system with the collected real-world data, initiating a second structural optimization on a different, second structure with a second pre-optimization simulated structural design that the retrained Generative AI system generated;
wherein the AI system further comprises a Generative AI capability to facilitate creation of new content in response to a query from a user, the method further comprising creating new images, text, and/or sound in response to a query from the user;
wherein the query is about at least one of the pre-optimization simulated structural design, the optimal simulated structural design, the physical structure, and the real-world data collected from the physical structure.

104. The method of claim 103, wherein the Generative AI capability to facilitate creation of new content in response to a query from a user is a Generative Pre-Trained Transformer (GPT).

105. The method of claim 103, wherein the method further includes the step of a choosing a pre-optimization simulated structural design from among a plurality of candidate pre-optimization simulated structural designs generated by the Generative AI system.

106. The method of claim 103, wherein the Generative AI system is trained on both synthetic and real-world data.

107. The method of claim 103, wherein the Generative AI system proposes multiple new structural designs it predicts will meet specified criteria.

108. The method of claim 103, wherein the Generative AI system proposes different structural designs for different optimization objective functions and/or optimization constraints.

109. The method of claim 103, further comprising the step of pre-processing the real-world data before the step of retraining the Generative AI system.

110. The method of claim 103, wherein the step of retraining the Generative AI system further includes retraining the Generative AI with data generated from optimizing the simulated structure.

111. The method of claim 103, further comprising generating a plurality of pre-optimization simulated structural designs and running multiple structural optimizations simultaneously therefrom.

112. The method of claim 103, further comprising the step of minting a non-fungible token (NFT) from at least one of: the pre-optimization simulated structural design, the optimal simulated structural design, and the real-world structure.

113. The method of claim 103, in which the Generative AI system considers data about a specific user in proposing a pre-optimization simulated structural design.
